(19) United States
(12) Patent Application Publication
(10) Pub. No.: US 2026/0169047 A1
(43) Pub. Date: Jun. 18, 2026

(54) SYSTEM, MEASURING INSTRUMENT, AND METHOD

(71) Applicant: Aeterlink Corp., Tokyo (JP)

(72) Inventors: Ryosuke KUMAGAI, Tokyo (JP); Naoto KODATE, Tokyo (JP)

(73) Assignee: Aeterlink Corp., Tokyo (JP)

(21) Appl. No.: 19/464,686

(22) Filed: Jan. 30, 2026

Related U.S. Application Data
(63) Continuation-in-part of application No. PCT/JP2024/021466, filed on Jun. 13, 2024.

(30) Foreign Application Priority Data
Jul. 31, 2023 (JP) 2023-123971

(51) Int. Cl. G01R 29/14; H02J 50/20; H02J 50/40

(52) U.S. Cl. CPC G01R 29/14; H02J 50/20; H02J 50/40

(57) ABSTRACT

A system includes one or more transmitters installed in a measurement target space and configured to transmit a wireless signal for supplying power, one or more receivers configured to generate electric power, using the wireless signal for supplying power, a plurality of measuring instruments configured to measure electric field intensity at respective positions at which the plurality of measuring instruments are disposed. An information processing apparatus configured to: store, in advance, space information of the measurement target space, and generate an electric field intensity distribution in the measurement target space based on (i) the space information and (ii) electric field intensity measured by the plurality of measuring instruments.

### CROSS-REFERENCE TO RELATED APPLICATIONS

This is a continuation-in-part of International Application No. PCT/JP2024/021466 filed on Jun. 13, 2024, and claims priority from Japanese Patent Application No. 2023-123971 filed on Jul. 31, 2023, the entire content of each are incorporated herein by reference.

### TECHNICAL FIELD

The present disclosure relates to system measuring instrument, and method.

### BACKGROUND ART

In recent years, wireless power transfer/transmission (WPT) has been used in various fields. By utilizing WPT, problems such as wiring burden, wire breakage, and maintenance, which occur in wired power transmission, can be avoided.

In JP2010-246319 describes an electric field intensity sensor that is installed in an indoor space and detects a level of an electromagnetic wave from a wireless power supply device received at an installation location, and also describes that a plurality of the electric field intensity sensors may be provided.

### SUMMARY OF INVENTION

Aspect of non-limiting embodiments of the present disclosure relates to providing a technique that enables an electric field intensity distribution in a measurement target space to be generated based on space information of the measurement target space and electric field intensity measured at a plurality of positions in the measurement target space.

Aspects of certain non-limiting embodiments of the present disclosure address the features discussed above and/or other features not described above. However, aspects of the non-limiting embodiments are not required to address the above features, and aspects of the non-limiting embodiments of the present disclosure may not address features described above.

According to an aspect of the present disclosure, there is provided a system including:
one or more transmitters installed in a measurement target space and configured to transmit a wireless signal for supplying power;
one or more receivers configured to generate electric power, using the wireless signal for supplying power;
a plurality of measuring instruments configured to measure electric field intensity at respective positions at which the plurality of measuring instruments are disposed; and
an information processing apparatus configured to:
   store, in advance, space information of the measurement target space; and
   generate an electric field intensity distribution in the measurement target space based on (i) the space information and (ii) electric field intensity measured by the plurality of measuring instruments.

### BRIEF DESCRIPTION OF DRAWINGS

Exemplary embodiment(s) of the present invention will be described in detail based on the following figures, wherein:

FIG. 1 is a diagram illustrating an overall configuration of a wireless power transmission (WPT) system 1 according to the present embodiment;

FIG. 2 is a block diagram illustrating a configuration example of the transmitter 100 and the receiver 200 shown in FIG. 1;

FIG. 3 is a block diagram illustrating a configuration example of a measuring instrument 500 shown in FIG. 1;

FIG. 4 is a diagram illustrating a functional configuration example of the first information processing apparatus 300;

FIG. 5A is a diagram illustrating an example of a structure of the measuring instrument 500 shown in FIG. 3; FIG. 5B is a diagram illustrating the example of the structure of the measuring instrument 500 shown in FIG. 3;

FIG. 6 is an example perspective view illustrating a structure of a PCB 530 shown in FIGS. 5A and 5B;

FIG. 7 is a perspective view illustrating the measuring instrument 500 shown in FIGS. 5A and 5B when placed on a plane;

FIG. 8 is a schematic diagram illustrating an example of a data structure of a space information table 3021 stored in the first information processing apparatus 300;

FIG. 9 is a schematic diagram illustrating an example of a data structure of a measurement result table 3022 stored in the first information processing apparatus 300;

FIG. 10 is a flowchart illustrating an example operation of the measuring instrument 500;

FIG. 11 is a diagram illustrating an example arrangement of the transmitter 100 and the measuring instrument 500 in a space;

FIG. 12 is a schematic diagram illustrating an example of a distribution map generated by a generation module 3034;

FIG. 13 is a diagram illustrating an example arrangement of the transmitter 100 and the measuring instrument 500 in a space;

FIG. 14 is a schematic diagram illustrating an example of a distribution map in a case where the transmitter 100 is arranged as shown in FIG. 13; and

FIG. 15 is a block diagram illustrating a basic hardware configuration of a computer 90.

### DESCRIPTION OF EMBODIMENTS

Hereinafter, embodiments of the present disclosure will be described below with reference to the drawings. In all drawings for describing the embodiments, the same reference numerals are assigned to common components, and repeated description thereof will be omitted.

The embodiments described below are not intended to unduly limit the subject matter of the present disclosure recited in the claims. Further, not all components shown in the embodiments are necessarily essential components of the present disclosure. Each drawing is schematic and is not necessarily drawn precisely.

### <Overview>

In a wireless power transmission (WPT) system, one or more transmitters configured to transmit a wireless signal for supplying power and a plurality of receivers configured to receive the wireless signal for supplying power are present. One or more measuring instruments measure electric field intensity based on the wireless signal for supplying power transmitted by the transmitter(s). An information processing apparatus calculates an electric-field-intensity distribution in a measurement target space (an indoor space) based on the electric field intensity measured by the measuring instrument(s).

### <1. Overall System Configuration>

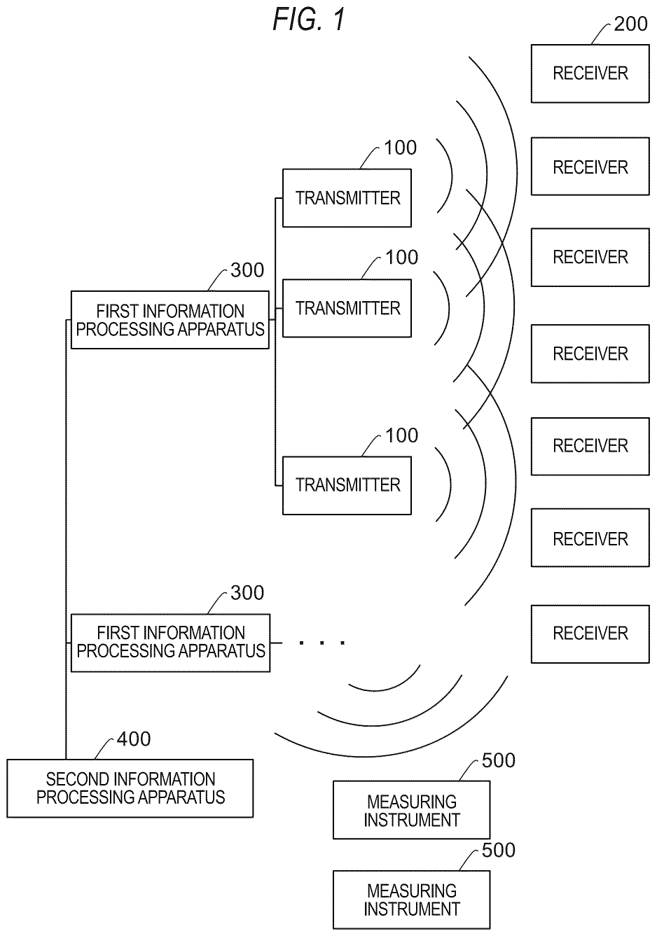

FIG. 1 is a diagram illustrating an overall configuration of the wireless power transmission (WPT) system 1 according to the present embodiment.

As illustrated in FIG. 1, the wireless power transmission (WPT) system 1 includes, for example, the transmitter 100, the receiver 200, the first information processing apparatus 300, the second information processing apparatus 400, and a measuring instrument 500. The wireless power transmission (WPT) system 1 illustrated in FIG. 1 is used, for example, in a building or a factory. A building is an example of a structure, and is not limited to a building so long as the space is an indoor space in which predetermined activities such as business activities and office work are performed. A connection between the transmitter 100 and the first information processing apparatus 300 and a connection between the first information processing apparatus 300 and the second information processing apparatus 400 may be wired or wireless.

In FIG. 1, an example in which the wireless power transmission (WPT) system 1 includes three transmitters 100 is illustrated; however, the number of transmitters 100 included in the wireless power transmission (WPT) system 1 is not limited to three. The number of transmitters 100 included in the wireless power transmission (WPT) system 1 may be two or fewer, or may be four or more.

In FIG. 1, an example in which the wireless power transmission (WPT) system 1 includes seven receivers 200 is illustrated; however, the number of receivers 200 included in the wireless power transmission (WPT) system 1 is not limited to seven. The number of receivers 200 included in the wireless power transmission (WPT) system 1 may be six or fewer, or may be eight or more.

In the present specification, the transmitter 100 is a (power) transmitter 100 in the sense that electric power is transmitted wirelessly, and similarly, the receiver 200 is a (power) receiver 200 in the sense that electric power is received wirelessly. As described later, the receiver 200 may transmit, as a data signal, information regarding a state of the receiver 200 or information regarding a measurement result by a sensor to the transmitter 100, and the transmitter 100 may receive such a data signal. In this case, the transmitter 100 functions as a receiver that receives the data signal, and the receiver 200 functions as a transmitter that transmits the data signal.

In FIG. 1, an example in which the wireless power transmission (WPT) system 1 includes two measuring instruments 500 is illustrated; however, the number of measuring instruments 500 included in the wireless power transmission (WPT) system 1 is not limited to two. The wireless power transmission (WPT) system 1 may include three or more measuring instruments 500. The measuring instrument 500 may be installed, for example, at a position corresponding to a position of the transmitter 100. For example, the measuring instrument 500 is installed at a substantially equal distance from each transmitter 100. The measuring instrument 500 may be installed, for example, at a position corresponding to a position of the receiver 200. For example, the measuring instrument 500 is provided near the receiver 200.

In FIG. 1, an example in which the wireless power transmission (WPT) system 1 includes two first information processing apparatuses 300 is illustrated; however, the number of first information processing apparatuses 300 included in the wireless power transmission (WPT) system 1 is not limited to two. The wireless power transmission (WPT) system 1 may include one first information processing apparatus 300, or may include three or more first information processing apparatuses 300.

The transmitter 100 transmits, for example, a wireless signal for supplying power or a data signal to the receiver 200. The transmitter 100 transmits, for example, the wireless signal for supplying power to the receiver 200 using radio waves in a 920 MHz band. The transmitter 100 transmits, for example, the data signal to the receiver 200 using radio waves in a 2.4 GHz band. The transmitter 100 may transmit the data signal using radio waves in the 920 MHz band.

The transmitter 100 may supply power, for example, to one receiver 200 or to a plurality of receivers 200. The transmitter 100 may transmit the data signal, for example, to one receiver 200 or to a plurality of receivers 200. The transmitter 100 may transmit, for example, the same data signal as another transmitter 100 or a different data signal from another transmitter 100. The transmitter 100 may transmit, for example, a predetermined command signal as the data signal to the receiver 200, or may transmit a predetermined signal as the data signal to the receiver 200.

The transmitter 100 receives, for example, the data signal transmitted from the receiver 200. The transmitter 100 may receive, for example, the data signal transmitted from one receiver 200, or may receive the data signal transmitted from a plurality of receivers 200. The transmitter 100 transmits the data signal transmitted from the receiver 200 to the first information processing apparatus 300. The transmitter 100 transmits information regarding a state of the transmitter 100 to the first information processing apparatus 300.

The receiver 200 receives, for example, the wireless signal for supplying power or the data signal transmitted from the transmitter 100. When the receiver 200 includes a power storage unit, for example, the receiver 200 converts the wireless signal for supplying power transmitted from the transmitter 100 into electric power and stores the converted electric power in the power storage unit. When the receiver 200 includes a predetermined sensor, for example, the receiver 200 converts the wireless signal for supplying power transmitted from the transmitter 100 into electric power and drives the sensor using the converted electric power. The receiver 200 may drive the sensor using the electric power stored in the power storage unit.

The receiver 200 transmits, for example, information regarding a state of the receiver 200 or information regarding a measurement result by the sensor to the transmitter 100 as the data signal.

The measuring instrument 500 measures, for example, an intensity of an electric field (electric field intensity) generated by the wireless signal for supplying power transmitted from the transmitter 100. The measuring instrument 500 measures, for example, intensities along three axes in an orthogonal coordinate system of an electric field generated by radio waves in the 920 MHz band transmitted from the transmitter 100. The measuring instrument 500 performs, for example, predetermined statistical processing on the measured electric field intensity. The measuring instrument 500 transmits the processed information to the first information processing apparatus 300, for example, using radio waves in the 2.4 GHz band.

The measuring instrument 500 may calculate electric power that can be generated by the received wireless signal for supplying power. The measuring instrument 500 calculates, for example, intensities along three axes in an orthogonal coordinate system of electric power that can be generated by radio waves in the 920 MHz band transmitted from the transmitter 100. The measuring instrument 500 performs, for example, predetermined statistical processing on the calculated electric power. The measuring instrument 500 transmits the processed information to the first information processing apparatus 300, for example, using radio waves in the 2.4 GHz band.

The first information processing apparatus 300 is an information processing apparatus that monitors operations of the transmitter 100 and the receiver 200 accommodated in the wireless power transmission (WPT) system 1. For example, the first information processing apparatus 300 determines, based on information regarding the state of the transmitter 100 and the state of the receiver 200 transmitted from the transmitter 100, whether the transmitter 100 or the receiver 200 is in a predetermined state. When it is determined that the transmitter 100 or the receiver 200 is in the predetermined state, the first information processing apparatus 300 transmits predetermined information to the second information processing apparatus 400.

The first information processing apparatus 300 also accumulates information regarding the transmitter 100 and the receiver 200 accommodated in the wireless power transmission (WPT) system 1. For example, the first information processing apparatus 300 stores, in a memory unit included in the first information processing apparatus 300, information regarding the state of the transmitter 100 and the state of the receiver 200 transmitted from the transmitter 100.

The first information processing apparatus 300 also controls an operation of the transmitter 100 accommodated in the wireless power transmission (WPT) system 1. For example, the first information processing apparatus 300 transmits a predetermined instruction or predetermined information to the transmitter 100.

The first information processing apparatus 300 also controls an operation of the second information processing apparatus 400.

The first information processing apparatus 300 also monitors a radio-wave environment of a space in which the wireless power transmission (WPT) system 1 is constructed. For example, the first information processing apparatus 300 stores, in a memory unit included in the first information processing apparatus 300, information transmitted from the measuring instrument 500. For example, the first information processing apparatus 300 calculates, based on the stored information and information regarding an arrangement of the transmitter 100, a distribution of electric field intensity in the space. The distribution of electric field intensity may be a three-dimensional distribution or may be a two-dimensional distribution. For example, the first information processing apparatus 300 calculates an appropriate arrangement of the transmitter 100 based on the calculated electric-field-intensity distribution.

The second information processing apparatus 400 is, for example, an information processing apparatus operated by an administrator of the wireless power transmission (WPT) system 1. When the second information processing apparatus 400 receives, from the first information processing apparatus 300, a notification indicating that the transmitter 100, the receiver 200, or both are in a predetermined state, the second information processing apparatus 400 presents to a user that the transmitter 100, the receiver 200, or both are in the predetermined state.

The second information processing apparatus 400 also analyzes information regarding the state of the transmitter 100 and the state of the receiver 200 accumulated in the first information processing apparatus 300, and presents predetermined information to the user. The predetermined information includes, for example, the following:
information regarding an arrangement of the transmitter 100;
information regarding an arrangement of the receiver 200;
information regarding power consumption; and
information regarding power intensity.

The second information processing apparatus 400 also analyzes information measured by the measuring instrument 500 and accumulated in the first information processing apparatus 300, and presents predetermined information to the user. The predetermined information includes, for example, the following:
an electric-field-intensity distribution in the space; ⋅ a temporal change in the electric-field-intensity distribution in the space; ⋅ a change in the electric-field-intensity distribution based on a change in a situation in the space (for example, a change in an arrangement of the transmitter 100 or a change in parameters); ⋅ a change in the electric-field-intensity distribution based on a change in a layout in the space (for example, rearrangement of desks or shelves); and ⋅ an optimal arrangement of the transmitter 100 (for example, in a case where the optimal arrangement is not calculated by the first information processing apparatus 300).

### <1.1 Configuration of Transmitter and Receiver>

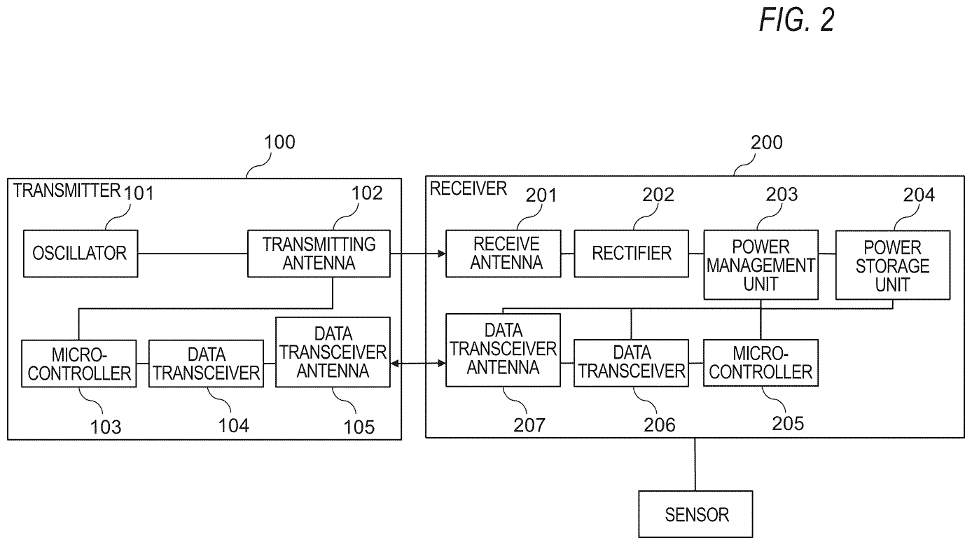

FIG. 2 is a block diagram illustrating a configuration example of the transmitter 100 and the receiver 200 shown in FIG. 1. As illustrated in FIG. 2, the transmitter 100 and the receiver 200 are, for example, separated from each other by a predetermined distance. For example, the transmitter 100 and the receiver 200 are installed with a separation distance of several meters. More specifically, for example, the transmitter 100 is fixedly installed at a predetermined elevated position in an indoor space, such as on a ceiling or a wall. Depending on how the transmitter 100 is installed, the position of the transmitter 100 may be changeable after installation. The receiver 200 is installed in a predetermined device in an indoor space, or is placed near a device that requires power supply. The receiver 200 may be carried by a user. Depending on how the receiver 200 is installed, the position of the receiver 200 may be changeable after installation. The transmitter 100 transmits the wireless signal for supplying power to the receiver 200 using radio waves at a predetermined frequency, such as in a 920 MHz band. The receiver 200 converts the wireless signal for supplying power transmitted from the transmitter 100 into electric power, and charges the converted electric power or supplies the converted electric power to a predetermined device.

The transmitter 100 includes, for example, an oscillator 101, a transmitting antenna 102, a microcontroller (MCU) 103, a data transceiver 104, and a data transceiver antenna 105. The oscillator 101, the microcontroller 103, the data transceiver 104, the data transceiver antenna 105, or at least any combination thereof may be mounted on the printed circuit board (PCB).

The oscillator 101 oscillates a signal in a predetermined frequency band, such as a 920 MHz band. The oscillated signal may be amplified as needed, and unnecessary frequency components may be removed.

The transmitting antenna 102 is formed to be capable of efficiently transmitting, for example, radio waves in the 920 MHz band. The transmitting antenna 102 radiates, as the wireless signal for supplying power, the signal oscillated by the oscillator 101.

The microcontroller 103 controls an operation of the transmitter 100. The microcontroller 103 is implemented, for example, by a semiconductor device including an ARM processor. The microcontroller 103 controls, for example, transmission of radio waves by the transmitting antenna 102.

The data transceiver 104 performs processing such as digital-to-analog conversion of digital data and modulation of analog data. The data transceiver 104 also performs processing such as demodulation of the data signal received by the data transceiver antenna 105 and digitization of the demodulated data. For example, the data transceiver 104 extracts a predetermined signal from the data signal received by the data transceiver antenna 105, converts the extracted signal into digital data, and transmits the digital data to the microcontroller 103.

The data transceiver antenna 105 is formed to be capable of efficiently transmitting and receiving, for example, radio waves in a 2.4 GHz band. The data transceiver antenna 105 radiates the data signal supplied from the data transceiver 104. The data transceiver antenna 105 also receives the data signal transmitted from the receiver 200.

The receiver 200 includes, for example, a receive antenna 201, a rectifier 202, a power management unit (PMU) 203, a power storage unit 204, a microcontroller 205, a data transceiver 206, and a data transceiver antenna 207. The receive antenna 201, the rectifier 202, the power management unit 203, the power storage unit 204, the microcontroller 205, the data transceiver 206, the data transceiver antenna 207, or at least any combination thereof may be mounted on a printed circuit board (PCB) or a flexible printed circuit (FPC).

The receive antenna 201 is formed to be capable of efficiently receiving, for example, radio waves in the 920 MHz band. The receive antenna 201 receives the wireless signal for supplying power radiated from the transmitting antenna 102.

The rectifier 202 rectifies the radio waves received as the wireless signal for supplying power and converts the rectified signal into a DC voltage.

The power management unit 203 manages the DC voltage. For example, the power management unit 203 controls a charging voltage based on the DC voltage. The power management unit 203 charges the power storage unit 204 by controlling the charging voltage. The power management unit 203 supplies the DC voltage to a connected member, for example, when electric power of not less than a predetermined capacity is stored in the power storage unit 204.

The power management unit 203 causes electric power stored in the power storage unit 204 to be discharged in accordance with control from the microcontroller 205.

The power storage unit 204 stores electric power in accordance with an instruction from the power management unit 203. The power storage unit 204 is implemented, for example, by a battery or a capacitor. The power storage unit 204 discharges the stored electric power in accordance with an instruction from the power management unit 203.

The microcontroller 205 controls an operation of the receiver 200. The microcontroller 205 is driven by the DC voltage supplied from the power management unit 203 or by electric power stored in the power storage unit 204. The microcontroller 205 controls the power management unit 203 to cause electric power stored in the power storage unit 204 to be discharged.

Various sensors are connectable to the receiver 200, for example. For example, a thermal sensor, a temperature sensor, an optical sensor, a humidity sensor, a vibration sensor, or the like is connected to the receiver 200. The sensor connected to the receiver 200 is driven, for example, by the DC voltage supplied from the power management unit 203 or by electric power discharged from the power storage unit 204. The microcontroller 205 continuously or intermittently monitors a voltage value at a predetermined portion of the receiver 200, a status of the sensor connected to the receiver 200, information detected by the sensor, and the like. The microcontroller 205 transmits, as digital data, the voltage value at the predetermined portion of the receiver 200, the status of the sensor connected to the receiver 200, the information detected by the sensor, and the like to the data transceiver 206. The sensor may be built into the receiver 200.

The data transceiver 206 performs processing such as digital-to-analog conversion of digital data supplied from the microcontroller 205 and modulation of analog data. The data transceiver 206 also performs processing such as demodulation of the data signal received by the data transceiver antenna 207 and digitization of the demodulated data. The data transceiver 206 is driven, for example, by the DC voltage supplied from the power management unit 203 or by electric power discharged from the power storage unit 204.

The data transceiver antenna 207 is formed to be capable of efficiently transmitting and receiving, for example, radio waves in a 2.4 GHz band. The data transceiver antenna 207 radiates the data signal supplied from the data transceiver 206. The data transceiver antenna 207 also receives the data signal transmitted from the transmitter 100. For example, the data transceiver antenna 207 is driven by a DC voltage supplied from the power management unit (PMU) 203 or by electric power discharged from the power storage unit 204.

### <1.2 Configuration of Measuring Instrument>

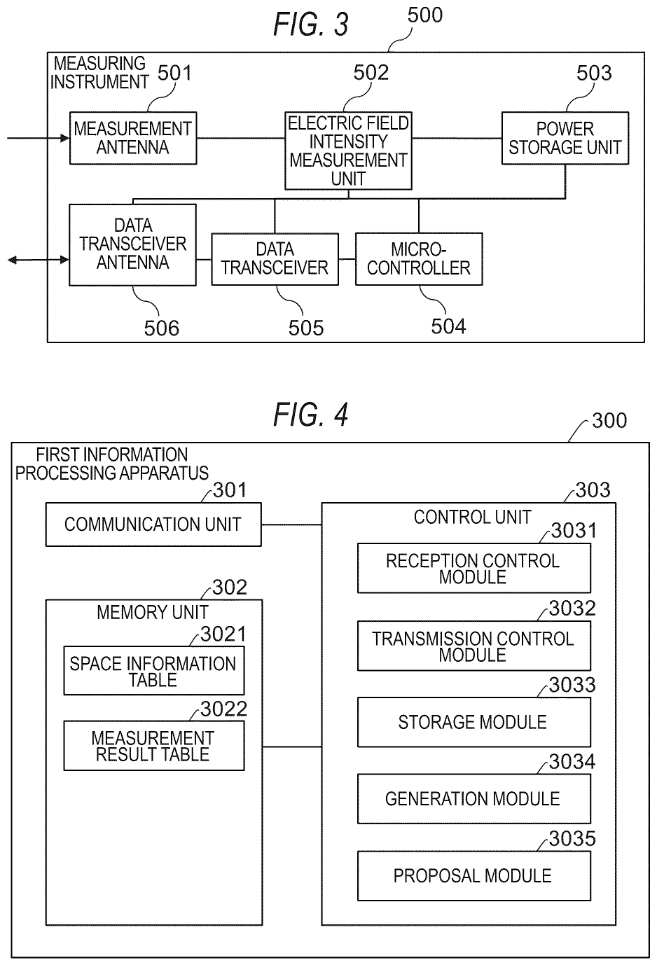

FIG. 3 is a block diagram illustrating a configuration example of the measuring instrument 500 shown in FIG. 1. The measuring instrument 500 shown in FIG. 3 is disposed, for example, in a measurement target space. For example, the measuring instrument 500 is disposed in the space at regular intervals. The measuring instrument 500 may be disposed, for example, only at positions where measurement is required. The measuring instrument 500 may be disposed, for example, at positions corresponding to the transmitter 100 or the receiver 200. The measuring instrument 500 may be placed on an object such as a desk, a chair, or a shelf, or may be suspended by a string. The measuring instrument 500 may be disposed not at a single height but at a plurality of heights.

The measuring instrument 500 includes, for example, a measurement antenna 501, an electric field intensity measurement unit 502, a power storage unit 503, a microcontroller 504, a data transceiver 505, and a data transceiver antenna 506. The measurement antenna 501, the electric field intensity measurement unit 502, the power storage unit 503, the microcontroller 504, the data transceiver 505, the data transceiver antenna 506, or at least any combination thereof may be mounted on a printed circuit board (PCB) or a flexible printed circuit (FPC).

The measurement antenna 501 is formed to be capable of efficiently receiving, for example, radio waves in the 920 MHz band. The measurement antenna 501 is formed, for example, along three axes in an orthogonal coordinate system. That is, the measurement antenna 501 includes an antenna element formed along an x-axis, an antenna element formed along a y-axis, and an antenna element formed along a z-axis. Each antenna element is implemented, for example, by a dipole antenna. Alternatively, each antenna element may be a monopole antenna. Each antenna element has, for example, a length not more than one half of a wavelength of radio waves in the 920 MHz band (for example, about 40 mm). The measurement antenna 501 receives the wireless signal for supplying power radiated from the transmitting antenna 102.

The electric field intensity measurement unit 502 measures electric field intensity based on an intensity of a signal received by the measurement antenna 501. More specifically, for example, the electric field intensity measurement unit 502 measures electric field intensity based on an intensity of a signal received for each antenna element of the measurement antenna 501. The electric field intensity measurement unit 502 measures, for example, electric field intensity at a predetermined cycle. The predetermined cycle is, for example, multiple times per second (about 1000 times). The electric field intensity measurement unit 502 outputs a measurement result to the microcontroller 504. The measurement result may be provided with a timestamp indicating a time at which the measurement was performed.

The power storage unit 503 stores, for example, electric power supplied from outside. The power storage unit 503 is implemented, for example, by a battery or a capacitor. The power storage unit 503 may store electric power generated by the wireless signal for supplying power transmitted from the transmitter 100. When the measuring instrument 500 is disposed while being connected to the receiver 200, the measuring instrument 500 may use the power storage unit 204 of the receiver 200. When the measuring instrument 500 is built into the receiver 200, the measuring instrument 500 may use the power storage unit 204 of the receiver 200.

The microcontroller 504 controls an operation of the measuring instrument 500. The microcontroller 504 executes statistical processing based on the measurement result measured by the electric field intensity measurement unit 502. The statistical processing includes, for example, calculation of an average value over a predetermined period and calculation of a peak value over the predetermined period. The statistical processing is not limited thereto, and various types of processing may be performed. The predetermined period corresponds, for example, to a period corresponding to a cycle at which the measuring instrument 500 transmits information regarding the measurement result. The predetermined period may be the same as the cycle at which the measuring instrument 500 transmits information regarding the measurement result, or may be shorter. The microcontroller 504 outputs, to the data transceiver 505, information regarding the measurement result, as information after the statistical processing or as information measured by the electric field intensity measurement unit 502. For example, the microcontroller 504 outputs information regarding the measurement result together with date and time at which the measurement was performed.

Based on the measurement result measured by the electric field intensity measurement unit 502, the microcontroller 504 may calculate electric power that would be generated if the measuring instrument 500 were the receiver 200. More specifically, for example, the microcontroller 504 stores information regarding an efficiency of a rectifier. For example, the efficiency of the rectifier varies depending on an intensity of a received wireless signal for supplying power and a magnitude of a connected load (a magnitude of a load of an application executed using the electric power to be generated). The microcontroller 504 calculates electric power based on the information regarding the efficiency of the rectifier and the measurement result measured by the electric field intensity measurement unit 502. The microcontroller 504 executes statistical processing on data regarding the calculated electric power. The microcontroller 504 outputs data after the statistical processing to the data transceiver 505. The microcontroller 504 may calculate electric power based on the data after the statistical processing.

A power switch may be connected to the microcontroller 504. Whether to drive the measuring instrument 500 is input by pressing the power switch. The microcontroller 504 operates when a user inputs that the power switch is turned on. The microcontroller 504 stops when a user inputs that the power switch is turned off.

The data transceiver 505 performs processing such as digital-to-analog conversion of digital data output from the microcontroller 504 and modulation of analog data. The data transceiver 505 also performs processing such as demodulation of the data signal received by the data transceiver antenna 506 and digitization of the demodulated data.

The data transceiver antenna 506 is formed to be capable of efficiently transmitting and receiving, for example, radio waves in a 2.4 GHz band. The data transceiver antenna 506 radiates the data signal output from the data transceiver 505. The data transceiver antenna 506 also receives the data signal transmitted from the first information processing apparatus 300.

### <1.3 Configuration of First Information Processing Apparatus>

FIG. 4 is a diagram illustrating an example of a functional configuration of the first information processing apparatus 300. As illustrated in FIG. 4, the first information processing apparatus 300 provides functions as a communication unit 301, a memory unit 302, and a control unit 303.

The communication unit 301 performs processing for the first information processing apparatus 300 to communicate with other apparatuses, such as the transmitter 100, the receiver 200, and the measuring instrument 500.

The memory unit 302 includes, for example, space information table 3021, measurement result table 3022, and the like. The tables stored in the memory unit 302 are not limited thereto. The memory unit 302 also stores, for example, a table that stores information regarding states of the transmitter 100 and the receiver 200.

Space information table 3021 is a table that stores information regarding a space to be measured. Details will be described later.

Measurement result table 3022 is a table that stores information regarding a measurement result. Details will be described later.

The control unit 303 is implemented by a processor reading a program stored in a memory unit and executing instructions included in the program. By operating in accordance with the program, the control unit 303 provides functions illustrated as a reception control module 3031, a transmission control module 3032, a storage module 3033, a generation module 3034, and a proposal module 3035.

The reception control module 3031 controls processing in which the first information processing apparatus 300 receives, in accordance with a communication protocol, signals from other apparatuses, such as the transmitter 100, the second information processing apparatus 400, and the measuring instrument 500.

The transmission control module 3032 controls processing in which the first information processing apparatus 300 transmits, in accordance with a communication protocol, signals to other apparatuses, such as the transmitter 100, the second information processing apparatus 400, and the measuring instrument 500.

The storage module 3033 stores, in the memory unit 302, information acquired from the transmitter 100 and the measuring instrument 500. More specifically, for example, information regarding a measurement result is transmitted from the measuring instrument 500 at a predetermined cycle. The storage module 3033 acquires information output from the measuring instrument 500 and stores the acquired information in the measurement result table 3022.

The generation module 3034 generates a distribution map in a space to be measured based on information regarding measurement. More specifically, for example, the generation module 3034 refers to the measurement result table 3022 and generates a distribution map of electric field intensity in the space. The generation module 3034 may generate a two-dimensional distribution map or may generate a three-dimensional distribution map. When electric power is calculated by the measuring instrument 500, the generation module 3034 may generate a distribution map of electric power.

The proposal module 3035 calculates an arrangement of the transmitter 100 suitable for the space based on the distribution map in the space. The proposal module 3035 may calculate an optimal arrangement of the transmitter 100 while considering not only a change in position of the transmitter 100 but also, for example, an increase or a decrease in the number of transmitters 100. The proposal module 3035 may calculate an optimal arrangement of the transmitter 100 while changing not only the arrangement of the transmitter 100 but also, for example, parameters such as an orientation in which the transmitter 100 is arranged and an intensity of radio waves to be radiated. For example, the proposal module 3035 estimates a relationship between an electric field and the transmitter 100 based on the calculated distribution map, and adjusts the number, positions, and parameters of the transmitter 100 such that electric field intensity in the space becomes a recommended state.

### <2 Structure of Measuring Instrument>

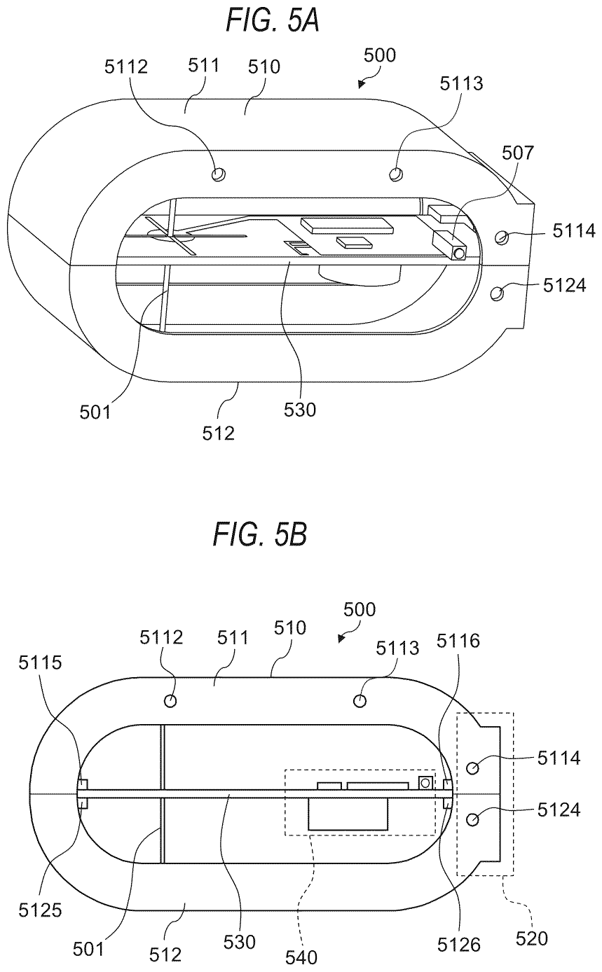

FIGS. 5A and 5B are example diagrams illustrating a structure of the measuring instrument 500 shown in FIG. 3. FIG. 5A illustrates an example perspective view of the measuring instrument 500, and FIG. 5B illustrates a side view of the measuring instrument 500. In the measuring instrument 500 illustrated in FIGS. 5A and 5B, for example, printed circuit board (PCB) 530 on which a circuit for the measuring instrument 500 is formed is housed in a case 510. The measuring instrument 500 has a longitudinal length of about 10 cm and a widthwise length and a depthwise length each of about 5 cm. In the example illustrated in FIGS. 5A and 5B, a portion of a side surface of the case 510 is hollow; however, the side surface of the case 510 is not limited to being hollow.

The case 510 is implemented by, for example, a resin such as polyvinyl chloride. The case 510 includes, for example, a first member 511 and a second member 512. The first member 511 and the second member 512 each have an arch shape. The case 510 is formed by fixing the first member 511 and the second member 512 to each other while the first member 511 and the second member 512 contact each other at leg portions of the arch shape. By fixing the arch-shaped first member 511 and the arch-shaped second member 512 at the leg portions, an internal space is formed.

Projections 5115 and 5116 are formed on an inner side of the leg portions of the first member 511. Projections 5125 and 5126 are formed on an inner side of the leg portions of the second member 512. When the first member 511 and the second member 512 are fixed to each other, a distance between the projection 5115 and the projection 5125 corresponds to a thickness of printed circuit board (PCB) 530. A distance between the projection 5116 and the projection 5126 corresponds to the thickness of printed circuit board (PCB) 530. Printed circuit board (PCB) 530 is held in the case 510 by being sandwiched between the projections 5115 and 5125 and between the projections 5116 and 5126.

On printed circuit board (PCB) 530, measurement antenna 501 and another circuit region 540 are formed along the longitudinal direction. In the circuit region 540, for example, electric field intensity measurement unit 502, power storage unit 503, microcontroller (MCU) 504, data transceiver 505, and data transceiver antenna 506 are mounted. The circuit region 540 is formed, for example, on both surfaces of printed circuit board (PCB) 530.

In the case 510, one end in a direction in which the circuit region 540 is formed is shaped to be placeable on a plane. For example, in FIGS. 5A and 5B, one end in the direction in which the circuit region 540 is formed is formed to be flat, thereby forming a placement portion 520. For accurate measurement by the measuring instrument 500, it is desirable that the placement portion 520 be formed along a plane defined by axes of the measurement antenna 501.

Holes 5112 and 5113 are formed in the first member 511 along the longitudinal direction. The holes 5112 and 5113 are formed at the same positions on a back side of the surface illustrated in FIGS. 5A and 5B. The holes 5112 and 5113 may be formed in the second member 512, or may be formed in both the first member 511 and the second member 512. The holes 5112 and 5113 are a mechanism for installing the measuring instrument 500 in midair at, for example, a height substantially the same as that of a desk or at a predetermined height. For example, the measuring instrument 500 can be fixed in midair by passing a linear object such as a thread, a string, or a wire, which is stretched between desks or the like, through the holes 5112 and 5113. For accurate measurement by the measuring instrument 500, it is desirable that the holes 5112 and 5113 be formed along an axial direction of the measurement antenna 501.

A hole 5114 is formed in the first member 511 at one end in the direction in which the circuit region 540 is formed. A hole 5124 is formed in the second member 512 at one end in the direction in which the circuit region 540 is formed. When the first member 511 and the second member 512 are fixed to each other, the hole 5114 and the hole 5124 are formed along the widthwise direction. The holes 5114 and 5124 are formed at the same positions on the back side of the surface illustrated in FIGS. 5A and 5B. The holes 5114 and 5124 may be formed at an end on a side where the measurement antenna 501 is formed, or may be formed at both ends. The holes 5114 and 5124 are a mechanism for installing the measuring instrument 500 in midair. For example, the measuring instrument 500 can be fixed in midair by passing a linear object such as a thread, a string, or a wire through the holes 5114 and 5124. For accurate measurement by the measuring instrument 500, it is desirable that the holes 5114 and 5124 be formed along an axial direction of the measurement antenna 501.

The holes 5112, 5113, 5114, and 5124 may be any installation mechanism that allows the measuring instrument 500 to be installed in midair by passing a linear object therethrough, and do not need to be holes. For example, the installation mechanism may be a hook.

The switch 507 is attached at a position where a user can press the switch 507 from a side surface of the case 510.

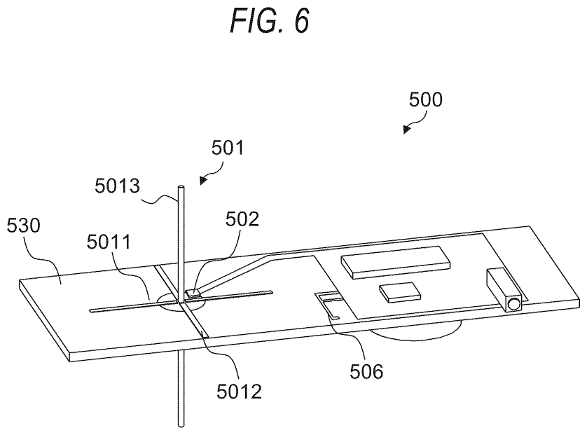

FIG. 6 is an example perspective view illustrating a structure of printed circuit board (PCB) 530 shown in FIGS. 5A and 5B. In FIG. 6, the measurement antenna 501 includes antenna elements 5011, 5012, and 5013 formed respectively along three axes in an orthogonal coordinate system. A longitudinal direction of printed circuit board (PCB) 530 is formed along a direction in which the antenna element 5011 is formed. A widthwise direction of printed circuit board (PCB) 530 is formed along a direction in which the antenna element 5012 is formed. The electric field intensity measurement unit 502 may be mounted, for example, near a region in which the antenna elements 5011, 5012, and 5013 are formed. This makes it possible to measure electric field intensity more accurately.

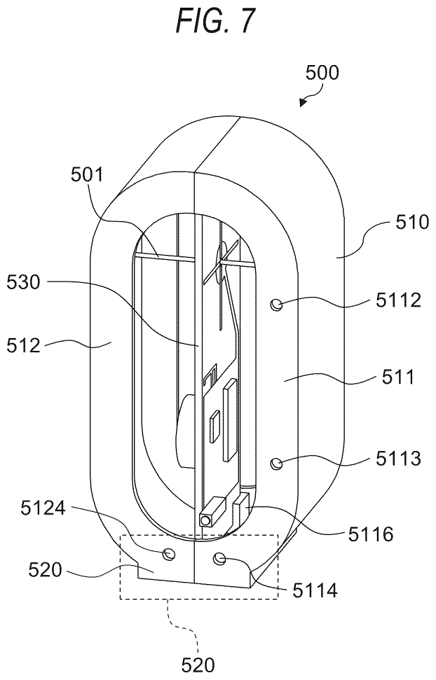

FIG. 7 is a perspective view illustrating the measuring instrument 500 shown in FIGS. 5A and 5B when placed on a plane. In FIG. 7, the measuring instrument 500 is placed on the plane by the placement portion 520. Because the placement portion 520 is provided at an end of the case 510 in the direction in which the circuit region 540 is formed, when the measuring instrument 500 is installed with the placement portion 520 in contact with the plane, the measurement antenna 501 is placed at a position separated from the plane. Accordingly, the measuring instrument 500 can suppress a decrease in reception efficiency of the measurement antenna 501.

### <3 Data Structure>

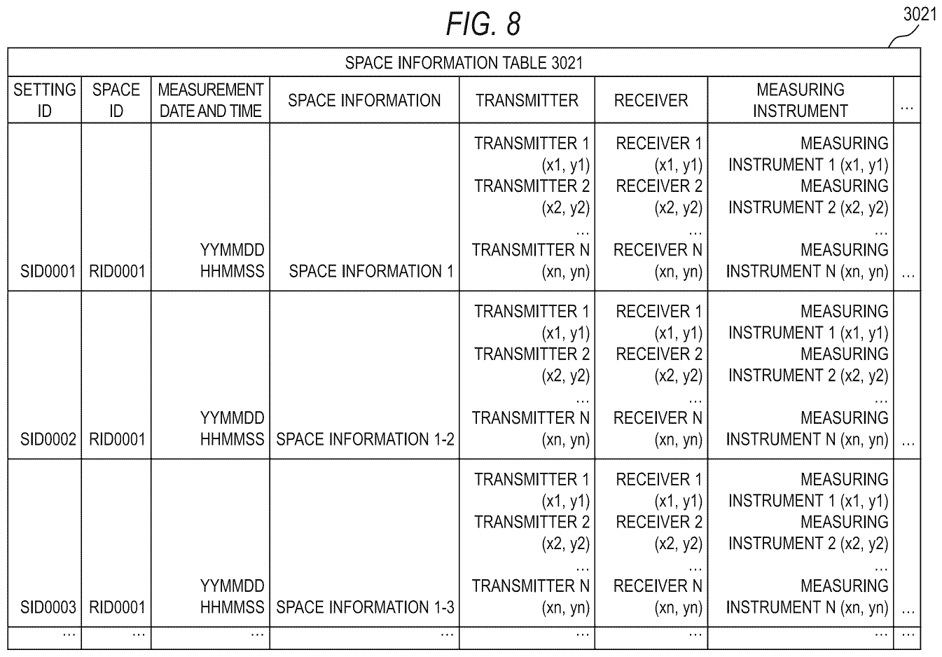

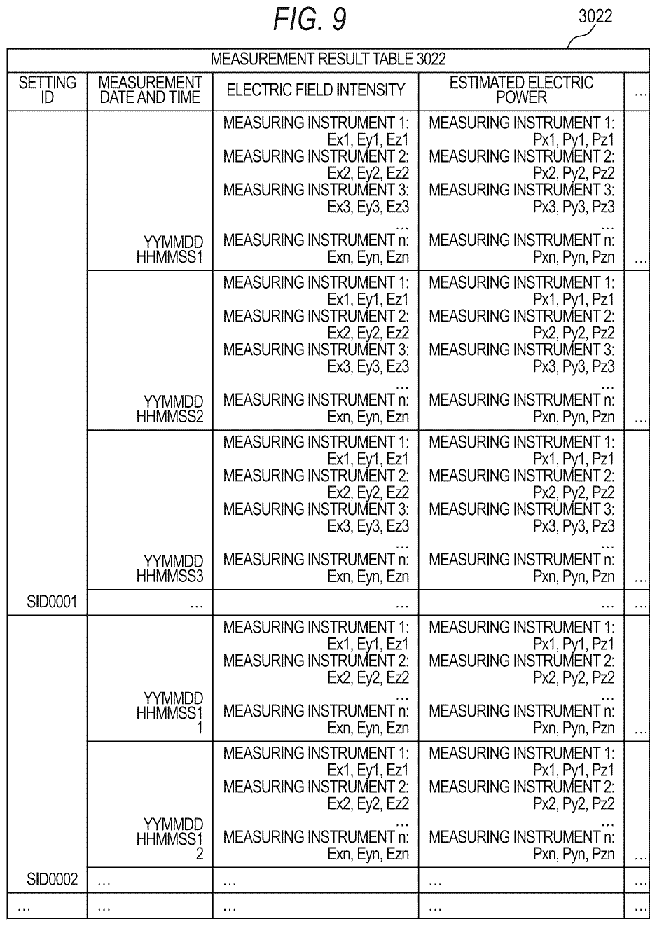

FIGS. 8 and 9 are diagrams illustrating data structures of tables stored in the first information processing apparatus 300. FIGS. 8 and 9 are merely examples, and do not exclude data that are not illustrated therein. Further, even data described in the same table may be stored in separate storage areas in the memory unit 302.

FIG. 8 is a schematic diagram illustrating an example data structure of space information table 3021 stored in the first information processing apparatus 300. Space information table 3021 illustrated in FIG. 8 is, for example, a table having columns of space ID, setting date and time, space information, transmitter, receiver, and measuring instrument, with setting ID as a key.

Setting ID is an item that stores identification information of a setting. Space ID is an item that stores identification information of a space. Setting date and time is an item that stores date and time at which information regarding the space was set. Space information is an item that stores information registered for the space. Space information includes, for example, a longitudinal distance of a room, a lateral distance of the room, a height of the room, information regarding materials forming the space, information regarding objects disposed in the space, information regarding loss of radio wave intensity in the space, or at least any combination thereof. The information regarding materials forming the space includes, for example, a floor material, a ceiling material, a wall material, a window glass material, or at least any combination thereof. The information regarding objects disposed in the space includes, for example, positions of objects such as a desk and a chair, types of the objects, materials of the objects, or at least any combination thereof. The space information may be stored in advance or may be set by a user. The space information is not limited thereto. For example, any of the above items may be absent, or other information may be included in addition to the above items.

Transmitter is an item that stores information regarding the transmitter 100. The transmitter item includes, for example, coordinates at which the transmitter 100 is disposed, transmission gain, transmission strength, or at least any combination thereof. Receiver is an item that stores information regarding the receiver 200. The receiver item includes, for example, coordinates at which the receiver 200 is disposed, reception gain, rectification efficiency, or at least any combination thereof. Measuring instrument is an item that stores information regarding the measuring instrument 500. The measuring instrument item includes, for example, coordinates at which the measuring instrument 500 is disposed.

FIG. 9 is a schematic diagram illustrating an example data structure of measurement result table 3022 stored in the first information processing apparatus 300. Measurement result table 3022 illustrated in FIG. 9 is, for example, a table having columns of measurement date and time, electric field intensity, and estimated electric power, with setting ID as a key.

Measurement date and time is an item that stores date and time at which measurement was performed. Electric field intensity is an item that stores measured electric field intensity. The electric field intensity item may store information subjected to statistical processing or may store information before statistical processing is performed. Estimated electric power is an item that stores calculated electric power. The estimated electric power item may store information subjected to statistical processing or may store information before statistical processing is performed. When electric power is not calculated, the estimated electric power item may be omitted.

### <4 Operation>

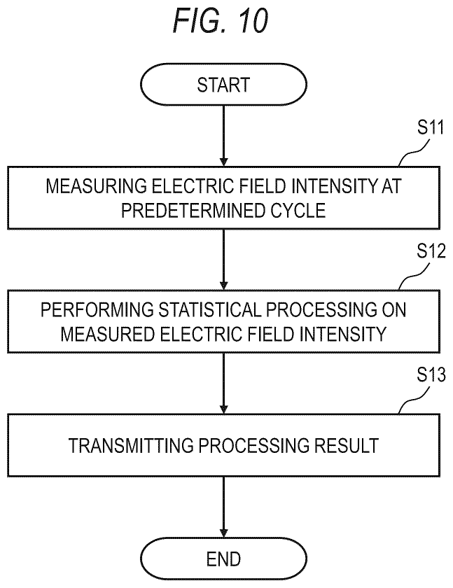

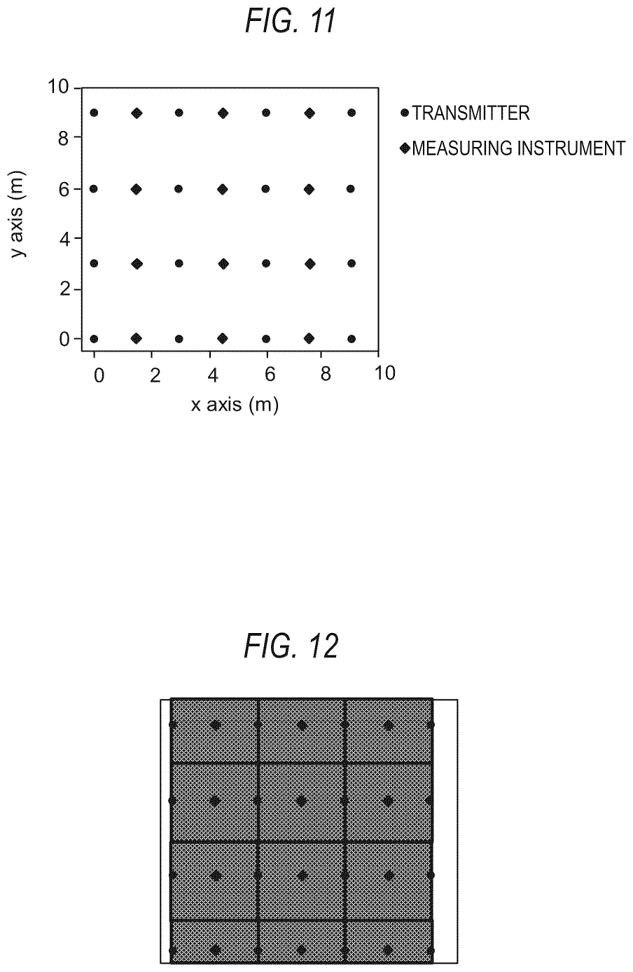

FIG. 10 is a flowchart illustrating an example operation of the measuring instrument 500. In the description of FIG. 10, a case will be described in which the transmitter 100 and the measuring instrument 500 are disposed, for example, as illustrated in FIG. 11.

FIG. 11 is a diagram illustrating an example arrangement of the transmitter 100 and the measuring instrument 500 in a space. The transmitter 100 and the measuring instrument 500 are disposed, for example, in an indoor space having 10 m in an x-direction and 10 m in a y-direction. The transmitter 100 is disposed, for example, at intervals of 3 m. The measuring instrument 500 is disposed, for example, such that a position in the y-direction is aligned with the transmitter 100 and a position in the x-direction is located between the transmitters 100.

In step S11, the measuring instrument 500 measures electric field intensity at a predetermined cycle. More specifically, the measurement antenna 501 receives radio waves in a 920 MHz band transmitted from the transmitter 100 using antenna elements 5011, 5012, and 5013 disposed along three axes in an orthogonal coordinate system. The electric field intensity measurement unit 502 measures electric field intensity for each axis based on an intensity of the radio waves received by the antenna elements 5011, 5012, and 5013 at, for example, a cycle of multiple times per second.

In step S12, the measuring instrument 500 performs statistical processing on the measured electric field intensity. More specifically, the microcontroller (MCU) 504 calculates, for example, electric field intensity for a one-second interval based on electric field intensity measured during one second. More specifically, the microcontroller (MCU) 504 calculates electric field intensity for the one-second interval by, for example, averaging electric field intensity measured during one second. Further, the microcontroller (MCU) 504 may set, for example, a peak value of electric field intensity measured during one second as electric field intensity for the one-second interval. A period for the statistical processing is not limited to one second and may be longer than one second.

In step S13, the measuring instrument 500 transmits information after the processing to the first information processing apparatus 300. More specifically, the microcontroller (MCU) 504 transmits information subjected to statistical processing to the first information processing apparatus 300 at a predetermined cycle. The predetermined cycle may coincide with the period for the statistical processing or may be longer than the period. The microcontroller (MCU) 504 may transmit an average value and a peak value of electric field intensity to the first information processing apparatus 300. The microcontroller (MCU) 504 may transmit a difference between the average value and the peak value of electric field intensity to the first information processing apparatus 300. The microcontroller (MCU) 504 may transmit a measurement result not subjected to statistical processing to the first information processing apparatus 300.

Upon receiving information regarding measurement from the measuring instrument 500, the first information processing apparatus 300 stores the received information in the measurement result table 3022. When predetermined information is requested from the second information processing apparatus 400, the first information processing apparatus 300 executes processing according to the request. For example, when electric field intensity distribution in the space is requested from the second information processing apparatus 400, the generation module 3034 generates a distribution map in the space to be measured based on information regarding measurement accumulated in the measurement result table 3022.

FIG. 12 is a schematic diagram illustrating an example distribution map generated by the generation module 3034. In FIG. 12, the space is divided into predetermined grids, and electric field intensity is represented by colors of the grids. Division of the grids is set, for example, based on an arrangement of the measuring instruments 500. The grids may be set by disposing the measuring instruments 500, or the measuring instruments 500 may be disposed to match the grids.

Further, for example, when a temporal change of electric field intensity distribution is requested from the second information processing apparatus 400, the generation module 3034 generates distribution maps of electric field intensity at a plurality of time points based on information regarding measurement accumulated in the measurement result table 3022.

Further, for example, when a change in electric field intensity distribution based on a change in a situation in the space or a change in layout is requested from the second information processing apparatus 400, the generation module 3034 refers to the space information table 3021 and acquires date and time at which a setting regarding the space was updated. The generation module 3034 acquires information regarding measurement before and after the update based on the measurement result table 3022, and generates a distribution map of electric field intensity based on the acquired information.

Further, for example, when a proposal for improving electric field intensity distribution is requested from the second information processing apparatus 400, the proposal module 3035 calculates an arrangement of the transmitter 100 suitable for the space based on the distribution map in the space.

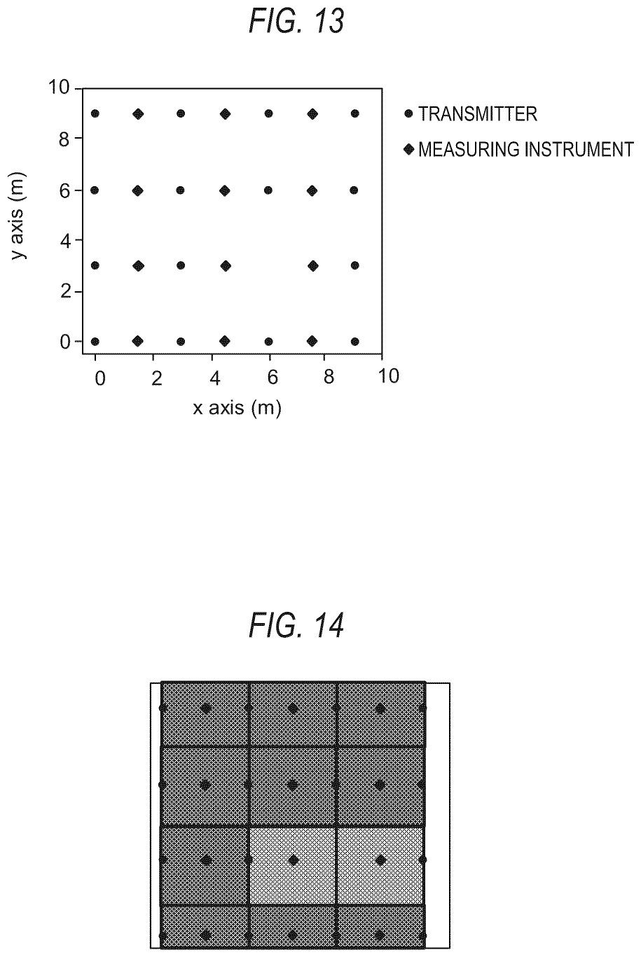

FIG. 13 is a diagram illustrating an example arrangement of the transmitter 100 and the measuring instrument 500 in the space. Unlike the example illustrated in FIG. 11, in FIG. 13, the transmitter 100 is not disposed at (x, y)=(6, 3).

FIG. 14 is a schematic diagram illustrating an example distribution map when the transmitter 100 is disposed as illustrated in FIG. 13. In FIG. 14, grids 31 and 32 have lower electric field intensity than other grids. The proposal module 3035 estimates a relationship between an electric field and the transmitter 100, and adjusts the number, positions, and parameters of the transmitter 100 such that electric field intensity in the space becomes a recommended state. The proposal module 3035 proposes disposing the transmitter 100 between the grid 31 and the grid 32 in FIG. 14, that is, at (x, y)=(6, 3).

As described above, in the above embodiment, the wireless power transmission (WPT) system 1 includes one or more transmitters 100, one or more receivers 200, a plurality of measuring instruments 500, and the first information processing apparatus 300. The transmitter 100 is installed in the measurement target space and transmits a wireless signal for supplying power. The receiver 200 generates electric power based on the wireless signal for supplying power. The measuring instrument 500 measures electric field intensity at a position where the measuring instrument 500 is disposed. The first information processing apparatus 300 stores, in advance, space information of the measurement target space, and generates electric field intensity distribution in the measurement target space based on the space information and electric field intensity measured by the measuring instrument 500. Accordingly, the first information processing apparatus 300 can acquire electric field intensity in the space in real time.

Accordingly, according to the wireless power transmission (WPT) system 1 of the present embodiment, radio wave intensity in the indoor space can be grasped.

Further, in the above embodiment, the measuring instruments 500 are disposed at regular intervals in the measurement target space. Accordingly, the first information processing apparatus 300 can acquire electric field intensity in the space without bias.

Further, in the above embodiment, the measuring instruments 500 are disposed at positions corresponding to an arrangement of the transmitters 100. Accordingly, the first information processing apparatus 300 can monitor, with high accuracy, intensity of a signal transmitted from the transmitters 100.

Further, in the above embodiment, the measuring instrument 500 sets rectification efficiency of the receiver 200 based on predetermined conditions, and calculates electric power generated by the receiver 200 based on the measured electric field intensity. Accordingly, the first information processing apparatus 300 can acquire electric power in the space in real time.

Further, in the above embodiment, the first information processing apparatus 300 generates at least two electric field intensity distributions having different measurement times. Accordingly, the first information processing apparatus 300 can acquire a temporal change of radio wave intensity in the space.

Further, in the above embodiment, the first information processing apparatus 300 generates at least two electric field intensity distributions under situations in which the space information is different. Accordingly, the first information processing apparatus 300 can acquire radio wave intensity in spaces having different settings in the same space.

Further, in the above embodiment, the measuring instrument 500 is capable of measuring electric field intensity on three axes. The first information processing apparatus 300 generates electric field intensity distribution based on electric field intensity measured on the three axes. Accordingly, when an arrangement of the transmitter 100 is considered, a polarization plane of the wireless signal for supplying power can also be considered.

Further, in the above embodiment, the first information processing apparatus 300 calculates an optimal arrangement of the transmitter 100 based on the generated electric field intensity distribution. Accordingly, the first information processing apparatus 300 can efficiently improve a radio wave environment in the space.

Further, in the above embodiment, the measuring instrument 500 includes the measurement antenna 501, a measurement unit that measures electric field intensity, namely the electric field intensity measurement unit 502, a generation unit that generates information, namely the microcontroller (MCU) 504, and a transmission unit that transmits information, namely the data transceiver antenna 506. The measurement antenna 501 receives radio waves transmitted from one or more transmitters that supply electric power wirelessly. The electric field intensity measurement unit 502 measures electric field intensity multiple times per second based on the received radio waves. The microcontroller (MCU) 504 generates information based on the measured electric field intensity. The data transceiver antenna 506 transmits the generated information. In the wireless power transmission (WPT) system 1 of the present embodiment, a plurality of transmitters 100 transmit wireless signals for supplying power asynchronously and without directivity. The wireless signal for supplying power transmitted from the transmitters 100 is reflected by multipath, and superposition and cancellation occur. Accordingly, temporal fluctuations in radio wave intensity are large. In the present embodiment, the electric field intensity measurement unit 502 measures electric field intensity 1000 times per second, and the microcontroller (MCU) 504 generates information based on the measured electric field intensity. Accordingly, electric field intensity can be measured with high accuracy in an environment in which a plurality of transmitters 100 transmit wireless signals for supplying power asynchronously and without directivity.

Further, in the above embodiment, the microcontroller (MCU) 504 generates information by performing statistical processing on the measured electric field intensity. Accordingly, the electric field intensity measurement unit 502 can suppress temporal fluctuations and acquire steady-state electric field intensity.

Further, the measuring instrument 500 may transmit not only information after the statistical processing but also measurement results. In this manner, measurement results obtained multiple times per second can be used in predetermined analysis.

Further, in the above embodiment, the microcontroller (MCU) 504 sets rectification efficiency of the receiver 200, which generates electric power by receiving radio waves transmitted from the transmitter 100, based on predetermined conditions, and calculates electric power generated by the receiver 200 based on the received radio waves. Accordingly, the measuring instrument 500 can estimate electric power in the space in real time.

Further, in the above embodiment, the measurement antenna 501 is disposed along three axes in an orthogonal coordinate system. The receiver 200 may be affected by a polarization plane due to a structure of the reception antenna 201. The measurement antenna 501 can receive radio waves on x-, y-, and z-axes, and the electric field intensity measurement unit 502 can measure intensities of radio waves on the x-, y-, and z-axes. Accordingly, because electric field intensity distribution can be generated based on electric field intensity measured on the three axes, a user can also consider an optimal placement of the receiver 200 by referring to the electric field intensity distribution.

Further, in the above embodiment, the measuring instrument 500 includes the case 510 that houses the measurement antenna 501 and the circuit region 540. The case 510 includes the placement portion 520 at one end. The measurement antenna 501 is housed near an end opposite to an end at which the placement portion 520 is formed. Accordingly, because the measurement antenna 501 is placed at a position separated from a placement surface, the measuring instrument 500 can suppress a decrease in reception efficiency of the measurement antenna 501.

### Modification

In the above embodiment, a case has been described as an example in which the first information processing apparatus 300 generates electric field intensity distribution or electric power distribution. However, the measuring instrument 500 may generate electric field intensity distribution or electric power distribution. In this case, for example, at least one of a plurality of measuring instruments 500 collects information regarding measurement from other measuring instruments 500. The measuring instrument 500 that has collected the information generates electric field intensity distribution or electric power distribution based on the collected information.

In the above embodiment, an example has been described in which the measurement antenna 501 includes antenna elements 5011, 5012, and 5013 formed respectively along three axes in an orthogonal coordinate system. However, the antenna elements included in the measurement antenna 501 may be an antenna element disposed along one axis in the orthogonal coordinate system, or may be antenna elements disposed along two axes in the orthogonal coordinate system.

In each of the above embodiments, application to the wireless power transmission (WPT) system 1, in which transmission power consisting of an AC signal is transmitted wirelessly from the transmitter 100 to the receiver 200, has been described. However, application to a system that provides electric power to the receiver 200 by a method other than the above is also naturally possible. Such systems are known, and thus detailed description thereof will be omitted. Examples include a system that outputs electric power generated by solar power generation to the receiver 200 regardless of whether a wired or wireless path is used, and a system that outputs electric power to the receiver 200 by laser light regardless of whether a wired or wireless path is used. In addition, a configuration in which vibration or sound is applied to the receiver 200 and the receiver 200 converts power of vibration or the like into electric power is also applicable. Further, application is also naturally possible to a system using a known non-contact power supply technology other than wirelessly receiving transmission power consisting of an AC signal, such as a non-contact power supply technology by magnetic field coupling.

### <5 Basic Hardware Configuration of Computer>

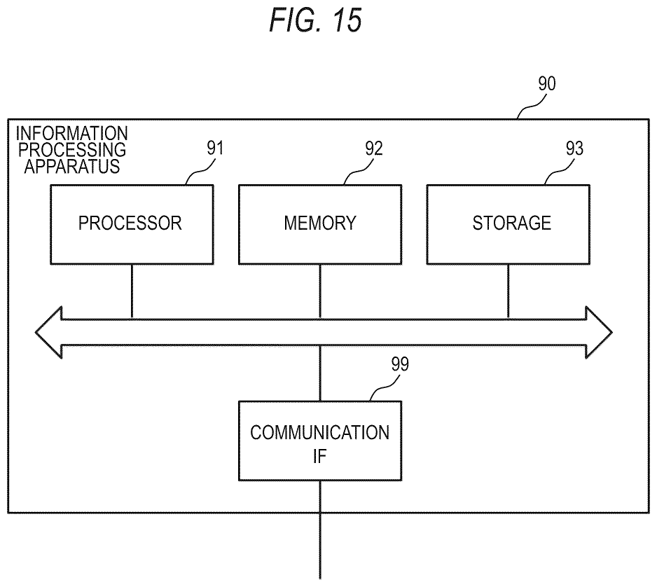

FIG. 15 is a block diagram illustrating a basic hardware configuration of a computer 90. The computer 90 includes at least a processor 91, a main storage device 92, an auxiliary storage device 93, and a communication interface 99. These are electrically connected to each other by a bus.

The processor 91 is hardware for executing an instruction set described in a program. The processor 91 includes an arithmetic unit, registers, peripheral circuits, and the like.

The main storage device 92 temporarily stores a program and data processed by the program and the like. For example, the main storage device 92 is a volatile memory such as DRAM.

The auxiliary storage device 93 is a storage device for storing data and programs. Examples thereof include a flash memory, a hard disk drive (HDD), a magneto-optical disk, a CD-ROM, a DVD-ROM, a semiconductor memory, and the like.

The communication interface 99 is an interface for inputting and outputting signals for communicating with another computer through a network using a wired or wireless communication standard.

The network includes various mobile communication systems constructed by the Internet, a LAN, a wireless base station, and the like. For example, the network includes a 3G, 4G, or 5G mobile communication system, LTE, and a wireless network connectable to the Internet by a predetermined access point, such as Wi-Fi. In a case of wireless connection, the communication protocol includes, for example, Z-Wave, ZigBee, and Bluetooth. In a case of wired connection, the network includes, for example, a network directly connected by a USB cable or the like.

All or part of each hardware configuration may be distributed among a plurality of computers 90 and interconnected to each other through a network, thereby virtually implementing the computer 90. In this manner, the computer 90 is a concept that includes not only a computer 90 housed in a single housing or case, but also a virtualized computer system.

### <Basic Functional Configuration of Computer 90>

A functional configuration of a computer implemented by the basic hardware configuration of the computer 90 illustrated in FIG. 15 will be described. The computer includes at least functional units of a control unit, a memory unit, and a communication unit.

The functional units included in the computer 90 may also be implemented by distributing all or part of each functional unit among a plurality of computers 90 interconnected to each other through a network. The computer 90 is a concept that includes not only a single computer 90, but also a virtualized computer system.

The control unit is implemented by the processor 91 reading various programs stored in the auxiliary storage device 93, developing the programs in the main storage device 92, and executing processing in accordance with the programs. The control unit can implement functional units that perform various types of information processing according to types of programs. Accordingly, the computer is implemented as an information processing apparatus that performs information processing.

The memory unit is implemented by the main storage device 92 and the auxiliary storage device 93. The memory unit stores data, various programs, and various databases. The processor 91 can secure, in the main storage device 92 or the auxiliary storage device 93, a storage area corresponding to the memory unit in accordance with a program. The control unit can cause the processor 91 to execute processing for addition, updating, and deletion of data stored in the memory unit in accordance with various programs.

A database refers to a relational database, and is for managing, in association with each other, a data set referred to as a table in a tabular form structurally defined by rows and columns. In a database, a table is referred to as a table, a column of a table is referred to as a column, and a row of a table is referred to as a record. In a relational database, relationships between tables can be set and associated.

Typically, each table is provided with a column serving as a key for uniquely identifying a record; however, setting a key for a column is not mandatory. The control unit can cause the processor 91 to execute, in accordance with various programs, processing for adding, deleting, and updating records in a specific table stored in the memory unit.

The communication unit is implemented by the communication interface 99. The communication unit implements a function of communicating with another computer 90 through a network. The communication unit can receive information transmitted from another computer 90 and input the information to the control unit. The control unit can cause the processor 91 to execute information processing on the received information in accordance with various programs. Further, the communication unit can transmit information output from the control unit to another computer 90.

Although some embodiments of the present disclosure have been described above, these embodiments can be implemented in various other forms, and various omissions, substitutions, and changes can be made without departing from the gist of the invention. These embodiments and modifications thereof are included in the scope and gist of the invention, and are also included in the invention described in the claims and equivalents thereof.

In the above description, a “processor” is one or more processors. At least one processor is typically a microprocessor such as a CPU, but may be another type of processor such as a GPU. At least one processor may be a single-core processor or a multi-core processor.

Further, at least one processor may be a processor in a broad sense, such as a hardware circuit that performs part or all of processing, such as an FPGA or an ASIC.

Further, in the above description, information from which an output is obtained with respect to an input may be described using an expression such as an “xxx table”. Such information may be data having any structure, or may be a learning model such as a neural network that produces an output with respect to an input. Accordingly, an “xxx table” may be referred to as “xxx information”.

Further, in the above description, a configuration of each table is merely an example, and one table may be divided into two or more tables, or all or part of two or more tables may be implemented as one table.

Further, in the above description, processing may be described with a “program” as a subject. However, because a program is executed by a processor to perform predetermined processing while appropriately using a memory unit and/or an interface unit, a subject of the processing may be a processor, or a device such as a controller having the processor, or a microcontroller (MCU).

A program may be installed in an apparatus such as a computer, or may be stored in, for example, a program distribution server or a computer-readable non-transitory recording medium. In the following description, two or more programs may be implemented as one program, or one program may be implemented as two or more programs.

Further, in the above description, an identification number is used as identification information for various targets; however, another type of identification information may be employed instead of an identification number, such as an identifier including alphabetic characters or symbols.

Further, in the above description, when elements of the same type are described without distinction, a reference sign, or a common sign among reference signs, may be used. When elements of the same type are described with distinction, an element identification number, or a reference sign, may be used.

Further, in the above description, control lines and information lines are illustrated as those considered necessary for description, and do not necessarily illustrate all control lines and information lines in a product. All configurations may be interconnected to each other.

### <Additional Notes>

The matters described in each of the above embodiments are additionally described below.

### (Note 1)

A system including:
one or more transmitters installed in a measurement target space and configured to transmit a wireless signal for supplying power;
one or more receivers configured to generate electric power, using the wireless signal for supplying power;
a plurality of measuring instruments configured to measure electric field intensity at respective positions at which the plurality of measuring instruments are disposed; and
an information processing apparatus configured to:
   store, in advance, space information of the measurement target space; and
   generate an electric field intensity distribution in the measurement target space based on (i) the space information and (ii) electric field intensity measured by the plurality of measuring instruments.

### (Note 2)

The system according to (Note 1), in which the plurality of measuring instruments are disposed at regular intervals in the measurement target space.

### (Note 3)

The system according to (Note 1), in which the plurality of measuring instruments are disposed at positions corresponding to arrangement of the one or more transmitters.

### (Note 4)

The system according to any one of (Note 1) to (Note 3),
in which each of the plurality of measuring instruments is configured to:
   set rectification efficiency of a receiver among the one or more receivers based on a predetermined condition; and
   calculate electric power generated by the receiver, based on the measured electric field intensity.

### (Note 5)

The system according to any one of (Note 1) to (Note 4), in which: the information processing apparatus is configured to generate at least two electric field intensity distributions corresponding to different measurement times.

### (Note 6)

The system according to any one of (Note 1) to (Note 5), in which: the information processing apparatus is configured to generate at least two electric field intensity distributions in situations in which the space information is different from each other.

### (Note 7)

The system according to any one of (Note 1) to (Note 6),
in which each of the plurality of measuring instruments is configured to measure the electric field intensity along three axes; and
the information processing apparatus is configured to generate the electric field intensity distribution, based on the electric field intensity measured along the three axes.

### (Note 8)

The system according to any one of (Note 1) to (Note 7), in which: the information processing apparatus is configured to calculate an optimal arrangement of the one or more transmitters based on the generated electric field intensity distribution.

### (Note 9)

A measuring instrument including:
an antenna configured to receive radio waves transmitted from one or more transmitters configured to supply electric power wirelessly;
an electric field intensity measurement unit configured to measure electric field intensity multiple times per second based on the received radio waves;
a microcontroller configured to generate information based on the measured electric field intensity; and
a transmission unit configured to transmit the generated information.

### (Note 10)

The measuring instrument according to (Note 9), in which: the microcontroller is configured to generate the information by performing statistical processing on the measured electric field intensity.

### (Note 11)

The measuring instrument according to (Note 9) or (Note 10),
in which the microcontroller is configured to:
   set rectification efficiency of a receiver configured to receive the radio waves transmitted from the one or more transmitters and generate electric power, based on a predetermined condition; and
      calculate, based on the received radio waves, electric power generated by the receiver.

### (Note 12)

The measuring instrument according to any one of (Note 9) to (Note 11), in which: the antenna includes antenna elements disposed along two axes in an orthogonal coordinate system.

### (Note 13)

The measuring instrument according to any one of (Note 9) to (Note 11), in which: the antenna includes antenna elements disposed along three axes in an orthogonal coordinate system.

### (Note 14)

The measuring instrument according to any one of (Note 9) to (Note 13), further including:
a case configured to store the antenna, the microcontroller, and the transmission unit, the case having a placement portion at a first end portion of the case,
in which the antenna is stored in a vicinity of a second end portion of the case, the second end portion begin located opposite to the first end portion.

### (Note 15)

A method executed by a measuring instrument including an antenna configured to receive radio waves transmitted from one or more transmitters configured to supply electric power wirelessly, the method including:
measuring electric field intensity multiple times per second, based on the received radio waves;
   generating information based on the measured electric field intensity; and
   transmitting the generated information.

### (Note 16)

A non-transitory computer-readable storage medium storing a program for causing a measuring instrument including an antenna configured to receive radio waves transmitted from one or more transmitters that supply electric power wirelessly to execute processing including:
measuring electric field intensity multiple times per second, based on the received radio waves;
generating information based on the measured electric field intensity; and
transmitting the generated information.

What is claimed is:

1. A system comprising:
one or more transmitters installed in a measurement target space and configured to transmit a wireless signal for supplying power;
one or more receivers configured to generate electric power, using the wireless signal for supplying power;
a plurality of measuring instruments configured to measure electric field intensity at respective positions at which the plurality of measuring instruments are disposed; and
an information processing apparatus configured to:
store, in advance, space information of the measurement target space; and
generate an electric field intensity distribution in the measurement target space, based on (i) the space information and (ii) electric field intensity measured by the plurality of measuring instruments.

2. The system according to claim 1, wherein the plurality of measuring instruments are disposed at regular intervals in the measurement target space.

3. The system according to claim 1, wherein the plurality of measuring instruments are disposed at positions corresponding to arrangement of the one or more transmitters.

4. The system according to claim 1,
wherein each of the plurality of measuring instruments is configured to:
set rectification efficiency of a receiver, among the one or more receivers, based on a predetermined condition; and
calculate electric power generated by the receiver, based on the measured electric field intensity.

5. The system according to claim 1, wherein the information processing apparatus is configured to generate at least two electric field intensity distributions corresponding to different measurement times.

6. The system according to claim 1, wherein the information processing apparatus is configured to generate at least two electric field intensity distributions in situations in which the space information is different from each other.

7. The system according to claim 1,
wherein each of the plurality of measuring instruments is configured to measure the electric field intensity along three axes, and
the information processing apparatus is configured to generate the electric field intensity distribution, based on the electric field intensity measured along the three axes.

8. The system according to claim 1, wherein the information processing apparatus is configured to calculate an optimal arrangement of the one or more transmitters, based on the generated electric field intensity distribution.

9. A measuring instrument comprising:
an antenna configured to receive radio waves transmitted from one or more transmitters configured to supply electric power wirelessly;
an electric field intensity measurement circuit configured to measure electric field intensity multiple times per second, based on the received radio waves;
a microcontroller configured to generate information based on the measured electric field intensity; and
a transmission antenna configured to transmit the generated information,
wherein the measuring instrument is configured to be used with an information processing apparatus, the information processing apparatus being configured to:
store space information regarding a measurement target space; and
generate an electric field intensity distribution in the measurement target space, based on (i) the space information and (ii) electric field intensity measured by a plurality of measuring instruments including the measuring instrument.

10. The measuring instrument according to claim 9, wherein the microcontroller is configured to generate the information by performing statistical processing on the measured electric field intensity.

11. The measuring instrument according to claim 9,
wherein the microcontroller is configured to:
set rectification efficiency of a receiver configured to receive the radio waves transmitted from the one or more transmitters and generate electric power, based on a predetermined condition; and
calculate, based on the received radio waves, electric power generated by the receiver.

12. The measuring instrument according to claim 9, wherein the antenna includes antenna elements disposed along two axes in an orthogonal coordinate system.

13. The measuring instrument according to claim 9, wherein the antenna includes antenna elements disposed along three axes in an orthogonal coordinate system.

14. The measuring instrument according to claim 9, further comprising:
a case configured to store the antenna, the microcontroller, and the transmission antenna, the case having a placement portion at a first end portion of the case,
wherein the antenna is stored in a vicinity of a second end portion of the case, the second end portion being located opposite to the first end portion.

15. A method executed by a measuring instrument used in a system,
the system including:
a plurality of measuring instruments disposed in a measurement target space and configured to measure electric field intensity at respective positions; and
an information processing apparatus configured to generate an electric field intensity distribution in the measurement target space, based on (i) space information regarding the measurement target space and (ii) electric field intensity measured by the plurality of measuring instruments,
the method comprising:
receiving, by an antenna, radio waves transmitted from one or more transmitters configured to supply electric power wirelessly;
measuring electric field intensity multiple times per second, based on the received radio waves;
generating information based on the measured electric field intensity; and
transmitting the generated information.
